(19) United States
(12) Patent Application Publication
(10) Pub. No.: US 2015/0035002 A1
(43) Pub. Date: Feb. 5, 2015

(54) Super Junction Semiconductor Device and Manufacturing Method

(71) Applicant: Infineon Technologies Austria AG, Villach (AT)

(72) Inventor: Hans Weber, Bayerisch Gmain (DE)

(21) Appl. No.: 13/955,894

(22) Filed: Jul. 31, 2013

(51) Int. Cl. H01L 29/739; H01L 29/66

(52) U.S. Cl. CPC H01L 29/7395; H01L 29/66333
USPC 257/139; 438/138

(57) ABSTRACT

A method for manufacturing a super junction semiconductor device includes forming a trench in an n-doped semiconductor body and forming a first p-doped semiconductor layer lining sidewalls and a bottom side of the trench. The method further includes removing a part of the first p-doped semiconductor layer at the sidewalls and at the bottom side of the trench by electrochemical etching, and filling the trench.

### BACKGROUND

Semiconductor devices such as super junction (SJ) semiconductor devices, e.g. SJ insulated gate field effect transistors (SJ IGFETs) are based on mutual space charge compensation of n- and p-doped regions in a semiconductor body allowing for an improved trade-off between low area-specific on-state resistance Rₒₙ×A and high breakdown voltage V_{br} between load terminals such as source and drain. In SJ semiconductor devices robustness during operation conditions such as avalanche generation, switching of inductive loads or cosmic radiation depends on an electric field profile and production tolerances.

It is desirable to improve a method of manufacturing a super junction semiconductor device with respect to device robustness and to provide a super junction semiconductor device with improved device robustness.

### SUMMARY

According to an embodiment, a method for manufacturing a super junction semiconductor device includes forming a trench in a semiconductor body of a first conductivity type. The method further includes forming a first semiconductor layer of a second conductivity type other than the first conductivity type lining sidewalls and a bottom side of the trench. The method further includes removing a part of the first semiconductor layer at the side walls and at the bottom side of the trench by electrochemical etching, and filling the trench.

According to another embodiment, a super junction semiconductor device includes a super junction structure including a first U-shaped semiconductor layer of a second conductivity type having opposite sidewalls and a bottom side. Each one of the opposite side walls of the first U-shaped semiconductor layer adjoins a compensation region of a complementary first conductivity type. The bottom side of the first U-shaped semiconductor layer adjoins a semiconductor body portion of the first conductivity type. The super junction semiconductor device further includes a filling material filling an inner area of the first U-shaped semiconductor layer.

According to yet another embodiment, a super junction semiconductor device includes a super junction structure including a first U-shaped semiconductor layer of a second conductivity type. The super junction semiconductor device further includes a filling material filling an inner area of the first U-shaped semiconductor layer. The super junction semiconductor device further includes a compensation region of a complementary first conductivity type. At least one pair of a semiconductor region of the first conductivity type and a semiconductor region of the second conductivity type is arranged between the first U-shaped semiconductor layer and the compensation region.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1 is a schematic cross-sectional view of a semiconductor body portion for illustrating a method of manufacturing a super semiconductor device in accordance with one embodiment.

FIG. 2 illustrates the embodiment of the semiconductor body portion of FIG. 1 after forming a trench in an n-doped semiconductor body.

FIG. 3 illustrates the embodiment of the semiconductor body portion of FIG. 2 after forming a p-doped semiconductor layer lining sidewalls and a bottom side of the trench.

FIG. 4 illustrates the embodiment of the semiconductor body portion of FIG. 3 while removing a part of the p-doped semiconductor layer at the sidewalls and at the bottom side of the trench by electrochemical etching.

FIG. 5 illustrates the embodiment of the schematic cross-sectional view of the semiconductor body portion of FIG. 4 after filling the trench.

FIG. 6 illustrates one embodiment of a super junction semiconductor device including a super junction structure with a U-shaped semiconductor compensation layer.

FIG. 7 is a schematic cross-sectional view of a semiconductor body portion for illustrating another embodiment of a method of manufacturing a super junction semiconductor device after removing the p-doped semiconductor layer from a bottom side of the trench and from a top side of the semiconductor body portion illustrated in FIG. 3.

FIG. 8 illustrates the embodiment of the semiconductor body portion of FIG. 7 after lining the sidewalls and the bottom side of the trench and after lining a top side of the semiconductor body portion with a second n-doped semiconductor layer.

FIG. 9 illustrates the embodiment of the semiconductor body portion of FIG. 8 after forming a third p-doped semiconductor layer lining sidewalls and a bottom side of the trench.

FIG. 10 illustrates the embodiment of the semiconductor body portion of FIG. 9 while removing a part of the third p-doped semiconductor layer at the sidewalls and at the bottom side of the trench by electrochemical etching.

FIG. 11 illustrates the embodiment of the semiconductor body portion of FIG. 10 after filling the trench.

FIG. 12 illustrates one embodiment of a super junction semiconductor device including a super junction structure with a U-shaped semiconductor compensation layer and spaced drift regions having different widths.

FIG. 13 illustrates one embodiment of a super junction semiconductor device including a super junction structure with a U-shaped semiconductor compensation layer and two types of drift regions differing in a number of gate trenches formed therein.

FIG. 14 illustrates one embodiment of a super junction semiconductor device including a super junction structure with a U-shaped semiconductor compensation layer, spaced drift regions having different widths and equally spaced gate trenches.

FIG. 15 is a schematic cross-sectional view of a semiconductor body portion for illustrating another embodiment of a method of manufacturing a super junction semiconductor device after forming a first p-doped sub-layer lining sidewalls and a bottom side of the semiconductor body portion illustrated in FIG. 2.

FIG. 16 is a schematic cross-sectional view of the semiconductor body portion of FIG. 15 after forming a second p-doped sub-layer on the first p-doped sub-layer.

### DETAILED DESCRIPTION

In the following detailed description, reference is made to the accompanying drawings, which form a part hereof, and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language that should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open and the terms indicate the presence of stated structures, elements or features but not preclude additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may be provided between the electrically coupled elements, for example elements that are controllable to temporarily provide a low-ohmic connection in a first state and a high-ohmic electric decoupling in a second state.

The Figures illustrate relative doping concentrations by indicating “−” or “+” next to the doping type “n” or “p”. For example, “n⁻” means a doping concentration that is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

FIGS. 1 to 5 illustrate schematic cross-sectional views of a portion of a semiconductor body 104 at different process stages during manufacturing of a super junction semiconductor device according to an embodiment.

Referring to the schematic cross-sectional view of FIG. 1, a semiconductor body 104 including an n⁺-doped semiconductor substrate 140 and an n-doped semiconductor layer 142 formed thereon is provided as a base material. The n-doped semiconductor layer 142 may be formed by epitaxial growth, for example, and may include one layer or multiple layers having different doping concentration. As an example, the n-doped semiconductor layer 142 may include a pedestal n-doped semiconductor layer adjoining the n⁺-doped semiconductor substrate 140 and may further include an n-doped drift layer adjoining the pedestal layer.

The n⁺-doped semiconductor substrate 140 may be a single-crystalline semiconductor material, for example silicon (Si), silicon carbide (SiC), germanium (Ge), silicon germanium (SiGe), gallium nitride (GaN) or gallium arsenide (GaAs). A distance between first and second sides of the semiconductor body 104 may range between 20 μm and 300 μm, for example. A normal to the first and second sides defines a vertical direction and directions orthogonal to the normal direction are lateral directions. A thickness d of the n-doped semiconductor layer 142 may be chosen in consideration of a target thickness of that volume which absorbs a blocking voltage in an operation mode of the super junction semiconductor device. A dopant concentration within the n-doped semiconductor layer 142 may correspond to a target dopant concentration of the n-doped drift regions of the super junction semiconductor device. The concentration of dopants within the n-doped semiconductor layer 142 may be subject to production tolerances, e.g. due to limited accuracy when setting a dopant concentration during epitaxial growth, for example.

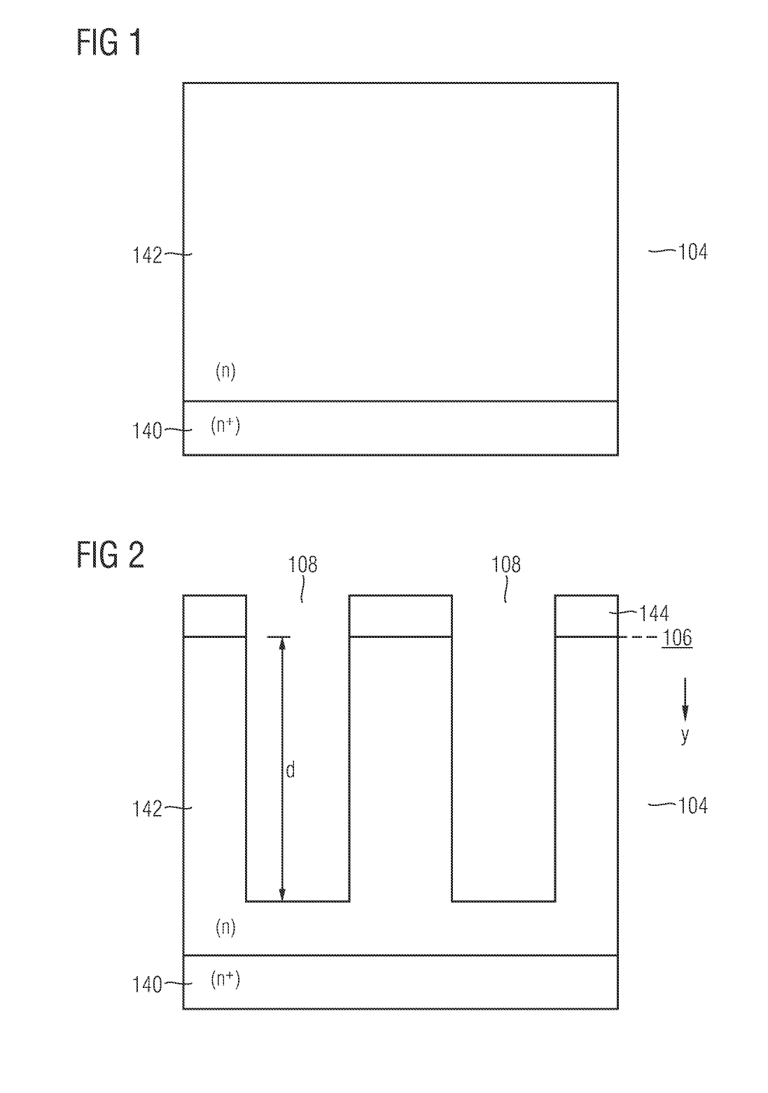

According to other embodiments, the semiconductor body 104 may not include an n⁺-doped semiconductor substrate 140, e.g. due to thinning of the semiconductor body 104 from a rear side. Referring to the schematic cross-sectional view of FIG. 2, a trench 108 is formed within the n-doped semiconductor layer 142 extending from a first side 106, e.g. a front side along a vertical direction y into a depth d of the semiconductor body 104. A portion of the n-doped semiconductor layer 142 between a bottom side of the trench 108 and the n⁺-doped semiconductor substrate 140 may include an optional pedestal layer that includes a different doping level than a remaining mesa portion of the n-doped semiconductor layer 142.

The trench 108 may be etched into the semiconductor body 104 by using an etch mask 144, e.g. a hard mask at the first side 106 of the semiconductor body 104. As an example, anisotropic etching such as reactive ion etching (RIE) may be used to form the trench 108. In the embodiment illustrated in FIG. 2, a bottom side of the trench remains within the n-doped semiconductor layer 142. A mesa region between neighboring trenches 108 may define a drift region.

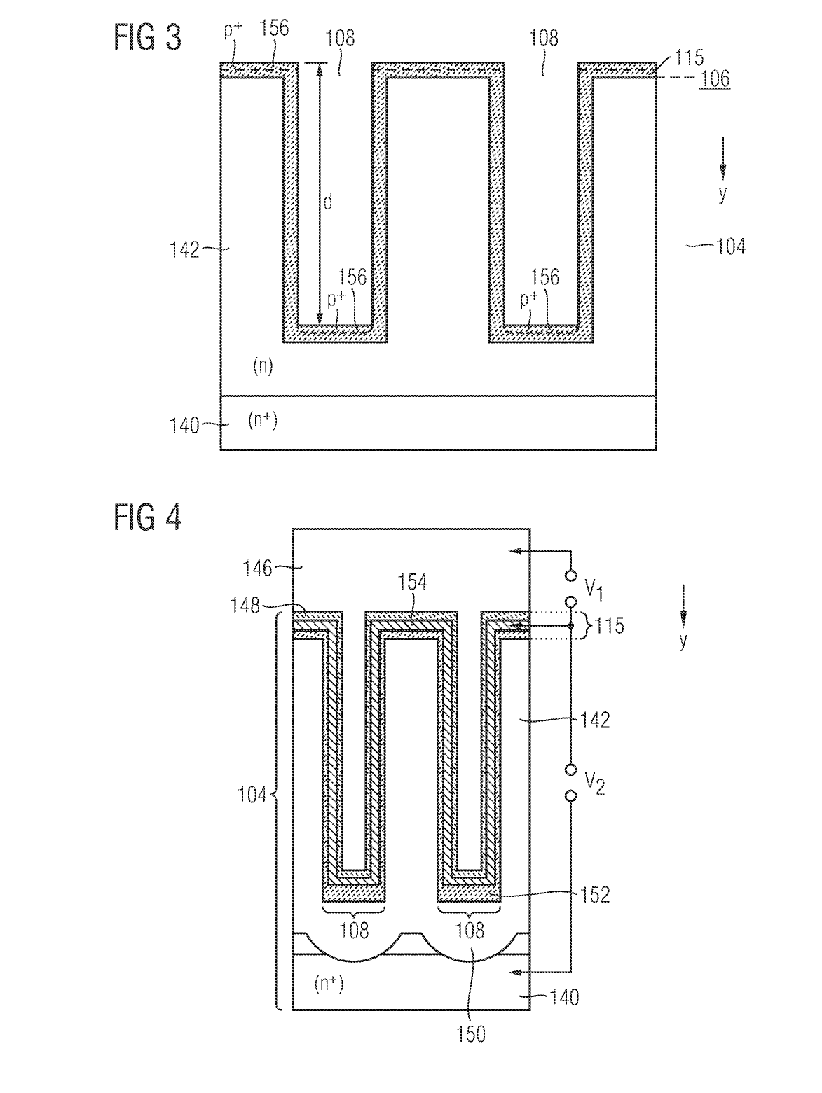

Referring to the schematic cross-sectional view of the semiconductor body 104 illustrated in FIG. 3, a p-doped semiconductor layer 115 is formed at the first 106 of the semiconductor body 104, at sidewalls and at a bottom side of the trench 108, e.g. by low pressure chemical vapor deposition (LPCVD). A contact region, e.g. a p⁺-doped region 156 may be formed in a part of the p-doped semiconductor layer 115 at a top side of the mesa region and at a bottom side of the trench 108. The p⁺-doped region 156 is illustrated in FIG. 3, but omitted in FIGS. 4 and 5 for the sake of clarity.

Referring to the schematic cross-sectional view of the semiconductor body 104 illustrated in FIG. 4, the p-doped semiconductor layer 115 is electrochemically etched, e.g. by alkaline wet etching using an alkaline solution 146. For example, when etching silicon, the alkaline solution 146 may include potassium hydroxide (KOH) or tetra-methyl ammonium hydroxide (TMAH). A voltage V between the alkaline solution 146 and the n-doped semiconductor body 104 divides into a voltage V₁ between the n-doped semiconductor layer 142 and the alkaline solution 146 and a voltage V₂ between the p-doped semiconductor layer 115 and the n-doped semiconductor body 104.

A junction between the alkaline solution 146 and the p-doped semiconductor layer 115 is similar to a Schottky barrier junction. Therefore, a Schottky depletion region 148 builds up at this interface. The voltage V₁ may short or forward bias a Schottky diode formed by the junction between the p-doped semiconductor layer 115 and the alkaline solution 146. A contact region, e.g. a p⁺-doped region that may be formed in a part of the p-doped semiconductor layer 115 at a top side of the mesa region may provide a low-ohmic electrical contact between the p-doped semiconductor layer 115 and the alkaline solution 146.

A voltage V₂ between the p-doped semiconductor layer 115 and the n-doped semiconductor body 104 is such that the pn junction between these regions is in a blocking mode and a space charge region including a first depletion layer 150 within the semiconductor body 104 and a second depletion layer 152 within the p-doped semiconductor layer 115 builds up. A value of V₂ may be chosen such that a volume of the semiconductor body 104 between the trenches 108, i.e. a drift region becomes depleted of free charge carriers. A thickness of the p-doped semiconductor layer 115 may be chosen such that the depletion regions 148, 152 do not meet after application of the voltages V₁, V₂. In other words, the voltages V₁ and V₂ may be such that a neutral volume 154 not constituting a space charge region remains.

Referring to the schematic cross-sectional view of the semiconductor body 104 illustrated in FIG. 5, etching of the p-doped semiconductor layer 115 is terminated once the depletion regions 152 and 148 meet. The volume of the p-doped semiconductor layer 115 includes two parts, namely first the Schottky depletion layer 148 and second the pn depletion layer 152. Charge compensation between the pn depletion layer 152 at one side of the trench 108 and one half of a mesa region of the n-doped semiconductor body 104 between neighboring trenches 108 is precise. This charge compensation is not affected by any production tolerances during manufacturing of device elements that may be present in case charge compensation depends upon variations in p- and n-doses introduced into the semiconductor body 104, e.g. variations in implant doses or variations of in-situ doping.

The charges of Schottky depletion layer 148 constitute excess charges with regard to an ideal charge compensation since the Schottky barrier does not remain after removal of the alkaline solution 146. These excess charges may be counterbalanced, maintained or partly maintained for electric field tuning for improving robustness or even removed in later process stages. As an example, charges of the Schottky depletion layer 148 may be partly or fully removed by isotropic dry etching or wet etching of a respective portion of p-doped semiconductor layer 115. As a further example, charges of the Schottky depletion layer 148 may also be removed by thermal oxidation of a respective portion of p-doped semiconductor layer 115 and subsequent removal of the oxide layer by an etch process, for example. As yet another example, charges of the Schottky depletion layer 148 may be counterbalanced by filling the trench 108 with an epitaxial semiconductor material having a conductivity type different from the conductivity type of the p-doped semiconductor layer 115. Partial or full removal of excess charges by above processes may be carried out after removal of the alkaline solution 146 and before filling the trench 108.

Regardless of whether the Schottky depletion layer 148 is partly or fully removed, at least a part of the p-doped semiconductor layer 115 remains at a bottom side of the trench 108. Thus, the p-doped semiconductor layer 115 is U-shaped and the p-doped semiconductor layer 115 at the bottom side of the trench 108 allows for adjusting an electric field peak profile at the bottom side of the trench 108. Thereby, robustness of a super junction semiconductor device can be improved.

Referring to the schematic cross-sectional view of the n-doped semiconductor body 104 illustrated in FIG. 5, the trench 108 is filled with a material 118. According to an embodiment, the trench 108 is filled with intrinsic and/or lightly doped semiconductor material(s). A doping concentration of lightly doped semiconductor material(s) may be such that an influence on the precise charge compensation due to electrochemical etching of the can be neglected or kept in an acceptable range. According to another embodiment, the trench 108 is filled with dielectric material(s), e.g. an oxide such as SiO₂ and/or a nitride such as Si₃N₄. The trench may also be filled by a combination of intrinsic and/or lightly doped semiconductor material(s) and dielectric material(s). Furthermore, a void 109 may be present in the material(s) 118 filling the trench 108. Formation of a void in the material(s) 118 filling the trench 108 may be due to process technology, for example.

Further processes may follow or be carried out before, between or together with the processes illustrated in FIGS. 1 to 5 to finalize the super junction semiconductor device. These processes may include formation of doped semiconductor regions within the semiconductor body 104, e.g. formation of source region(s), drain region(s), body region(s), contact region(s) via a first and/or second side of the n-doped semiconductor body, formation of gate structure(s) including gate electrode(s) and gate dielectric(s), wiring layer(s) and insulating layer(s) between wiring layers dielectric(s).

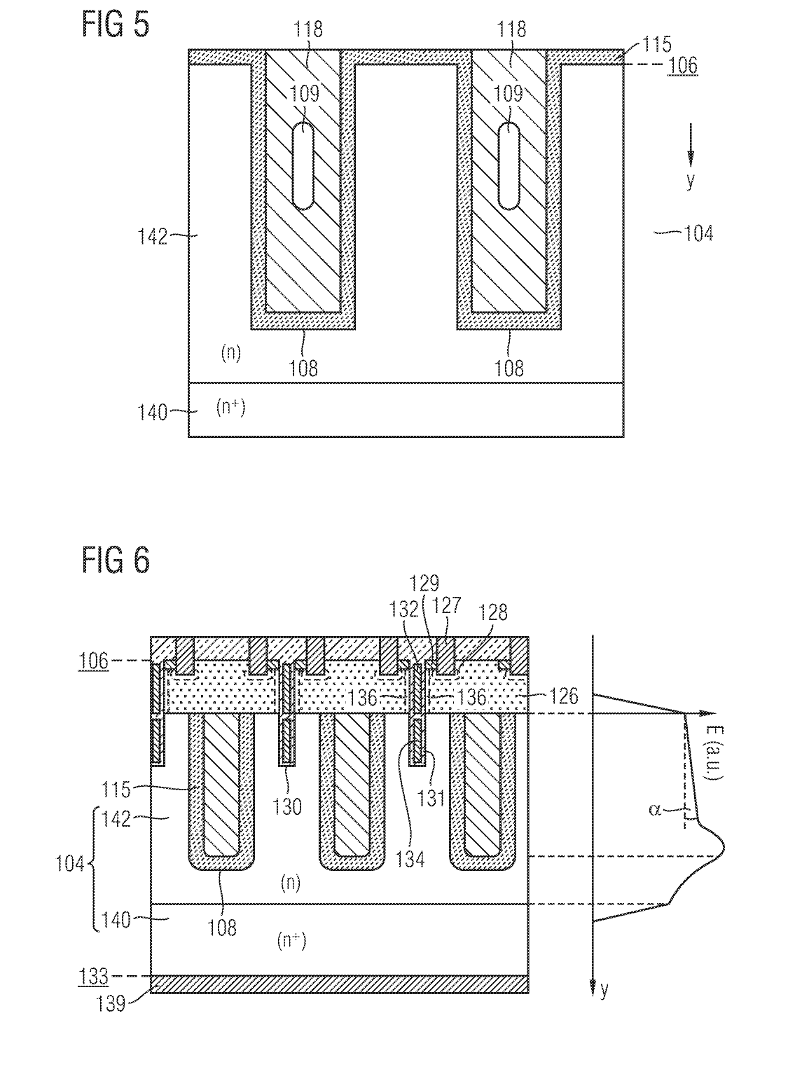

FIG. 6 illustrates one embodiment of a schematic cross-sectional view of a super junction semiconductor device. Above a super junction structure including the U-shaped p-doped semiconductor layer 115 and the n-doped semiconductor body 104 in between, a p-doped body region 126 is located and adjoins the U-shaped p-doped semiconductor layer 115. The p-doped body region 126 is electrically coupled to source contacts 127 via a p⁺-doped body contact zone 128. Sidewalls of the source contacts 127 are also electrically coupled to n⁺-doped source regions 129. Other contact schemes different from contact grooves for electrically coupling the body and source regions 128, 129 to the source contacts 127 may likewise apply. Between opposite source regions 129 a gate trench 130 extends through the p-doped body region 126 into the n-doped semiconductor body 104. A dielectric structure 131 electrically isolates a gate electrode 132 in an upper part of the gate trench 130 from a surrounding part of the p-doped body region 126, and furthermore electrically isolates a field electrode 134 in a lower part of the gate trench 130 from a surrounding part of the n-doped semiconductor body 104. By applying a voltage to the gate electrode 132 a conductivity along a channel region 136 can be controlled by field-effect. According to other embodiments, the gate trench 130 may include no field electrode or may include more than one field electrode. In case that no field electrode is located in the gate trench 130, the gate trench 130 may end slightly below a position where a bottom side of the p-doped body region 126 adjoins the gate trench 130. According to other embodiments, the super junction semiconductor device includes a planar gate structure at the first side 106.

The semiconductor device illustrated in FIG. 6 is a vertical super junction IGFET including a first load terminal, i.e. a source terminal including the source contacts 127 at the first side 106 of the n-doped semiconductor body 104 and a second load terminal, i.e. a drain terminal including a drain contact 139 at a second side 133 of the n-doped semiconductor body 104 opposite to the first side 106.

The super junction semiconductor device may be a super junction insulated gate field effect transistor (SJ IGFET), e.g. a SJ metal oxide semiconductor field effect transistor (SJ MOSFET), or a super junction insulated gate bipolar transistor (SJ IGBT). According to an embodiment, a blocking voltage of the semiconductor device ranges between 100 V and 5000 V, or between 200 V and 1000 V. The SJ transistor may be a vertical SJ transistor including one load terminal, e.g. a source terminal at the first side, e.g. a front side of the semiconductor body 100, and another load terminal, e.g. a drain terminal at the second side, e.g. a rear side of the semiconductor body 100.

The right part of FIG. 6 illustrates a vertical profile of the electric field in a voltage blocking or electric breakdown mode. The bottom side of the U-shaped p-doped semiconductor layer 115 causes a steeple-shaped electric field peak in blocking voltage/electric breakdown mode. By maintaining excess charges of the Schottky depletion layer 148, a slope α of the electric field can be adjusted. When increasing a p-loading in the super junction structure by maintaining more excess charges of the Schottky depletion layer 148, the angle α gets larger. The electric field peak allows for an increase in device robustness by improving a current/voltage characteristic with respect to positive differential resistance. Maintaining excess charges of the Schottky depletion layer 148 and forming the U-shaped p-doped semiconductor layer 115 constitute independent measures for forming a peak in the electric field profile. These measures may be applied in combination or individually.

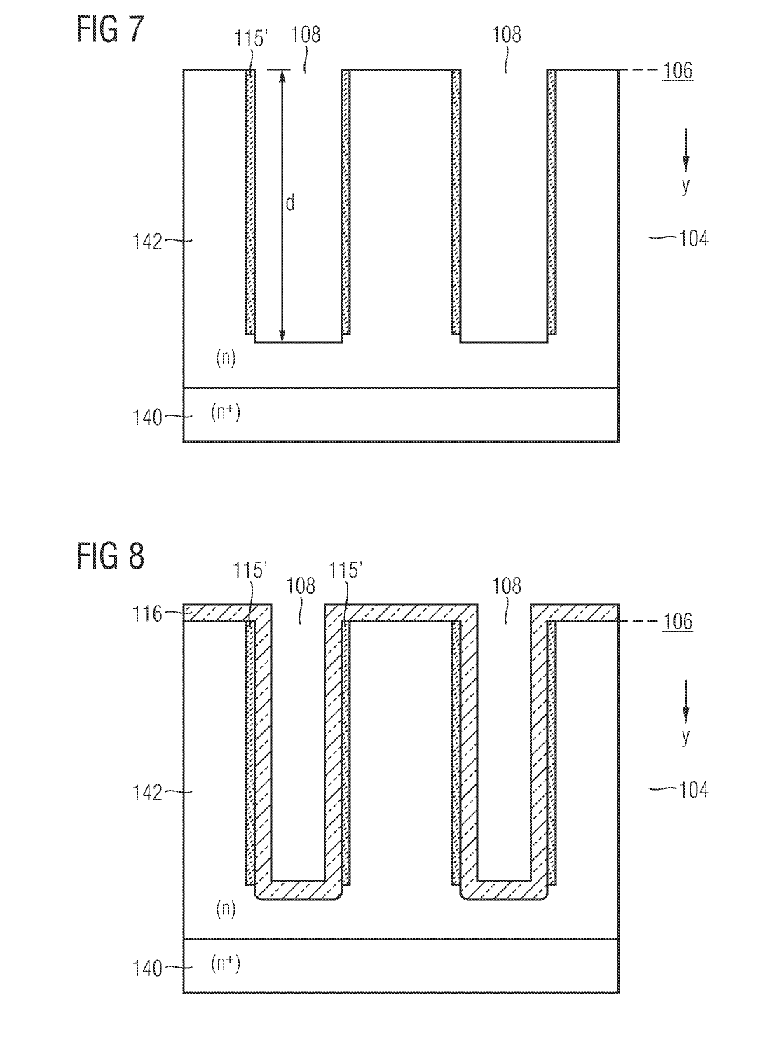

FIG. 7 is a schematic cross-sectional view of a semiconductor body portion for illustrating another embodiment of a method of manufacturing a super junction semiconductor device after removing the p-doped semiconductor layer 115 from a bottom side of the trench 108 and from a top side of the semiconductor body 104 illustrated in FIG. 3, resulting in a first p-doped semiconductor layer 115′. The p-doped semiconductor layer 115 may be removed by anisotropic etching using an appropriate process such as RIE.

FIG. 8 illustrates the embodiment of the schematic cross-sectional view of the semiconductor body 104 of FIG. 7 after lining the sidewalls and the bottom side of the trench 108 and after lining a top side of the semiconductor body 104 with a second n-doped semiconductor layer 116. The second n-doped semiconductor layer 116 may be formed by any appropriate process, e.g. by LPCVD.

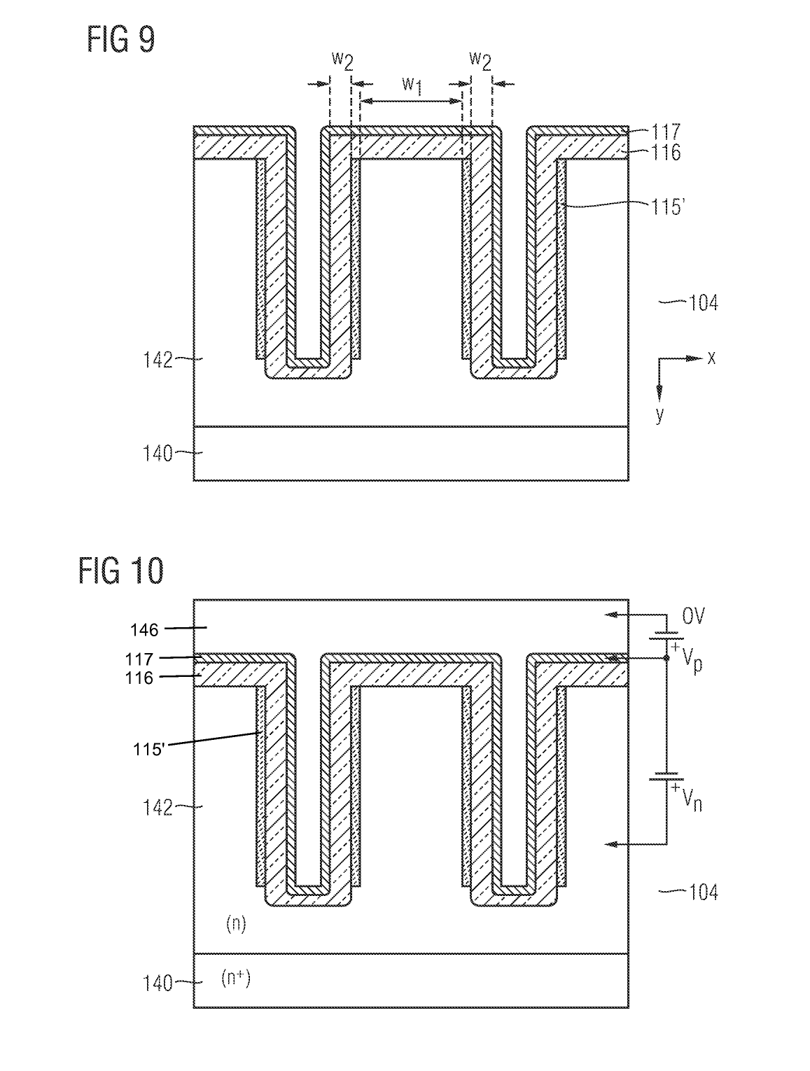

FIG. 9 illustrates the embodiment of the semiconductor body 104 of FIG. 8 after forming a third p-doped semiconductor layer 117 lining sidewalls and a bottom side of the trench 108. The third p-doped semiconductor layer 117 may be formed by any appropriate process, e.g. by LPCVD. According to the embodiment illustrated in FIG. 9, a first width w₁ of a part of the semiconductor body 104 between neighboring first p-doped layers 115′ is greater than a width w₂ of the second n-doped semiconductor layer 116. Each one of the part of the semiconductor body 104 between neighboring first p-doped layers 115′ and the second n-doped semiconductor layer 116 constitutes a drift region of a super junction semiconductor device manufactured with the method including the process features illustrated in FIGS. 1-5 and 7-10. According to an embodiment, a doping concentration N₁ of the part of the semiconductor body 104 between neighboring first p-doped layers 115′ is smaller than a doping concentration N₂ of the second n-doped semiconductor layer 116. The doping concentrations N₁, N₂ are doping concentrations averaged along a lateral direction x between confining pn junctions with respect to each one of the part of the semiconductor body 104 between neighboring first p-doped layers 115′ and the second n-doped semiconductor layer 116. In other words, the doping concentration N₁ is a doping concentration averaged along the arrow labelled w₁ in FIG. 9 whereas the doping concentration N₂ is a doping concentration averaged along the arrow labelled w₂ in FIG. 9.

Referring to the schematic cross-sectional view of the semiconductor body 104 illustrated in FIG. 10, the third p-doped semiconductor layer 117 is electrochemically etched, e.g. by alkaline wet etching using an alkaline solution 146. Processing of the third p-doped semiconductor layer 117 is similar to processing of the p-doped semiconductor layer 115 described with respect to FIG. 4. Thus, the information given above with respect to processing of the p-doped semiconductor layer 115 likewise applies to processing of the third p-doped semiconductor layer 117.

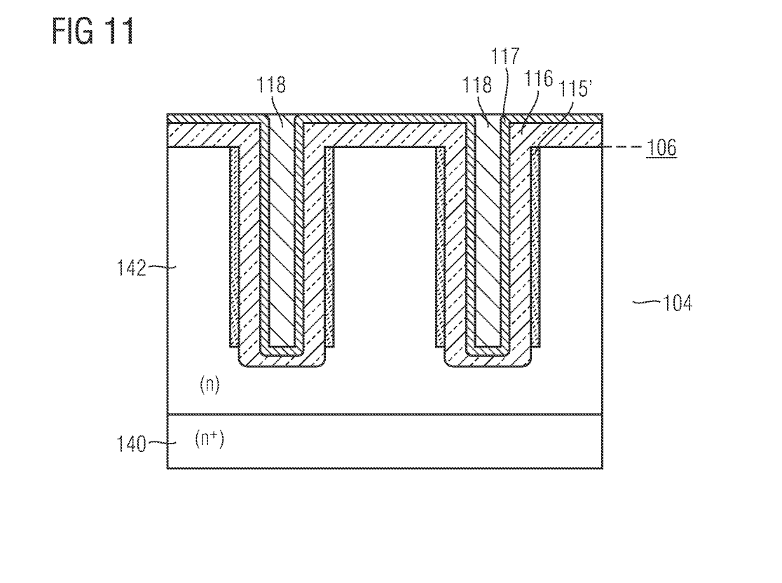

Referring to the schematic cross-sectional view of the n-doped semiconductor body 104 illustrated in FIG. 11, the trench 108 is filled with material 118. Similar to filling of the trench described with respect to FIG. 5, the trench 108 may be filled with intrinsic and/or lightly doped semiconductor material(s). A doping concentration of lightly doped semiconductor material(s) may be such that an influence on the precise charge compensation due to electrochemical etching of the can be neglected or kept in an acceptable range. According to another embodiment, the trench 108 is filled with dielectric material(s), e.g. an oxide such as SiO₂ and/or a nitride such as Si₃N₄. The trench may also be filled by a combination of intrinsic and/or lightly doped semiconductor material(s) and dielectric material(s). Furthermore, a void may be present in the material(s) 118 filling the trench 108. Formation of a void in the material(s) 118 filling the trench 108 may be due to process technology, for example.

Further processes may follow or be carried out before, between or together with the processes illustrated in FIGS. 1 to 3 and 7 to 11 to finalize the super junction semiconductor device. These processes may include formation of doped semiconductor regions within the semiconductor body 104, e.g. formation of source region(s), drain region(s), body region(s), contact region(s) via a first and/or second side of the n-doped semiconductor body, formation of gate structure(s) including gate electrode(s) and gate dielectric(s), wiring layer(s) and insulating layer(s) between wiring layers dielectric(s).

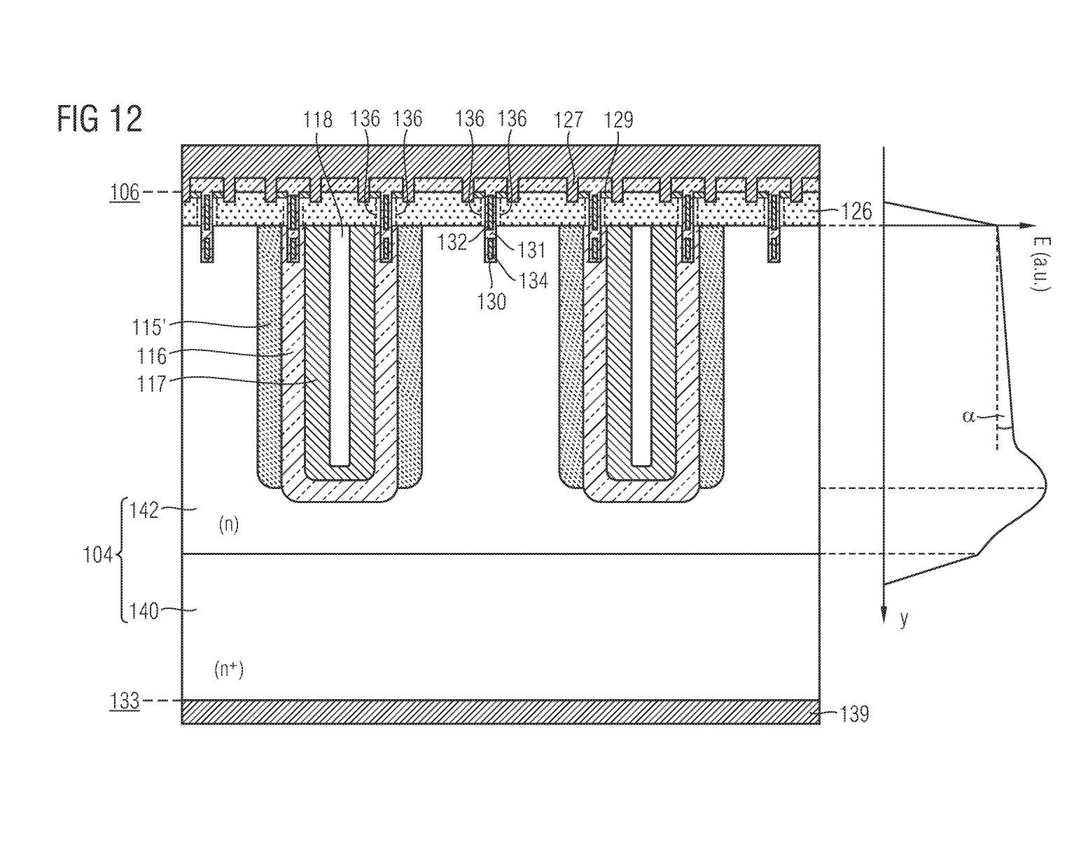

FIG. 12 illustrates one embodiment of a schematic cross-sectional view of a super junction semiconductor device that may be manufactured by a process including the process features described with reference to FIGS. 1 to 3 and 7 to 11.

The U-shaped third p-doped semiconductor layer 117 illustrated in FIG. 12 plays the role of the U-shaped p-doped semiconductor layer 115 illustrated in FIG. 6. Whereas the super junction semiconductor device illustrated in FIG. 6 includes one layer laterally between the material 118 and the n-doped semiconductor body 104, namely the U-shaped p-doped semiconductor layer 105, the super junction semiconductor device illustrated in FIG. 12 includes three layers between the material 118 and the n-doped semiconductor body 104, namely the U-shaped third p-doped semiconductor layer 117, the second n-doped semiconductor layer 116 and the first p-doped semiconductor layer 115′. A layer sequence between the filling material 118 and the n-doped semiconductor body 104 alternates between p- and n-type. According to other embodiments the super junction semiconductor device may include 5, or 7, or 9, or 11 layers between the material 118 and the n-doped semiconductor body 104, in general (n*2)+1 layers of alternating doping type, n being an integer equal or greater than 0.

Above a super junction structure including the U-shaped third p-doped semiconductor layer 117, the second n-doped semiconductor layer 116, the first p-doped semiconductor layer 115′ and the n-doped semiconductor body 104, a p-doped body region 126 is located and adjoins the U-shaped third p-doped semiconductor layer 117 and the first p-doped semiconductor layer 115′. The p-doped body region 126 is electrically coupled to source contacts 127 via a p⁺-doped body contact zone (e.g. see body contact zone 128 in FIG. 6). Sidewalls of the source contacts 127 are also electrically coupled to n⁺-doped source regions 129. Other contact schemes different from contact grooves for electrically coupling the body and source regions 128, 129 to the source contacts 127 may likewise apply. Gate trenches 130 extend through the p-doped body region 126 into the second n-doped semiconductor layer 106 and through the p-doped body region 126 into the n-doped semiconductor body 104. The dielectric structure 131 electrically isolates the gate electrode 132 in an upper part of the gate trench 130 from a surrounding part of the p-doped body region 126 and furthermore electrically isolates a field electrode 134 in a lower part of the trench 130 from a surrounding part of the n-doped semiconductor body 104 and from a surrounding part of the second n-doped semiconductor region 106, respectively. By applying a voltage to the gate electrode 132 a conductivity along the channel region 136 can be controlled by field-effect. According to other embodiments, the gate trench 130 may include no field electrode or may include more than one field electrode. In case that no field electrode is located in the gate trench 130, the gate trench 130 may end slightly below a position where a bottom side of the p-doped body region 126 adjoins the gate trench 130. According to other embodiments, the super junction semiconductor device includes a planar gate structure at the first side 106.

The semiconductor device illustrated in FIG. 12 is a vertical super junction IGFET including a first load terminal, i.e. a source terminal including the source contacts 127 at the first side 106 of the n-doped semiconductor body 104 and a second load terminal, i.e. a drain terminal including a drain contact 139 at a second side 133 of the n-doped semiconductor body 104 opposite to the first side 106.

The super junction semiconductor device may be a super junction insulated gate field effect transistor (SJ IGFET), e.g. a SJ metal oxide semiconductor field effect transistor (SJ MOSFET), or a super junction insulated gate bipolar transistor (SJ IGBT). According to an embodiment, a blocking voltage of the semiconductor device ranges between 100 V and 5000 V, or between 200 V and 1000 V. The SJ transistor may be a vertical SJ transistor including one load terminal, e.g. a source terminal at the first side, e.g. a front side of the semiconductor body 100, and another load terminal, e.g. a drain terminal at the second side, e.g. a rear side of the semiconductor body 100.

The right part of FIG. 12 illustrates a vertical profile of the electric field. The bottom side of the U-shaped third p-doped semiconductor layer 117 causes a steeple-shaped electric peak in blocking voltage/electric breakdown mode. By maintaining excess charges of the Schottky depletion layer 148 a slope α of the electric field can be adjusted. When increasing a p-loading in the super junction structure by maintaining more excess charges of the Schottky depletion layer 148 the angle α gets larger. The electric field peak allows for an increase in device robustness by improving a current/voltage characteristic with respect to positive differential resistance. Maintaining excess charges of the Schottky depletion layer 148 and forming the U-shaped third p-doped semiconductor layer 117 constitute independent measures for forming a peak in the electric field profile. These measures may be applied in combination or individually.

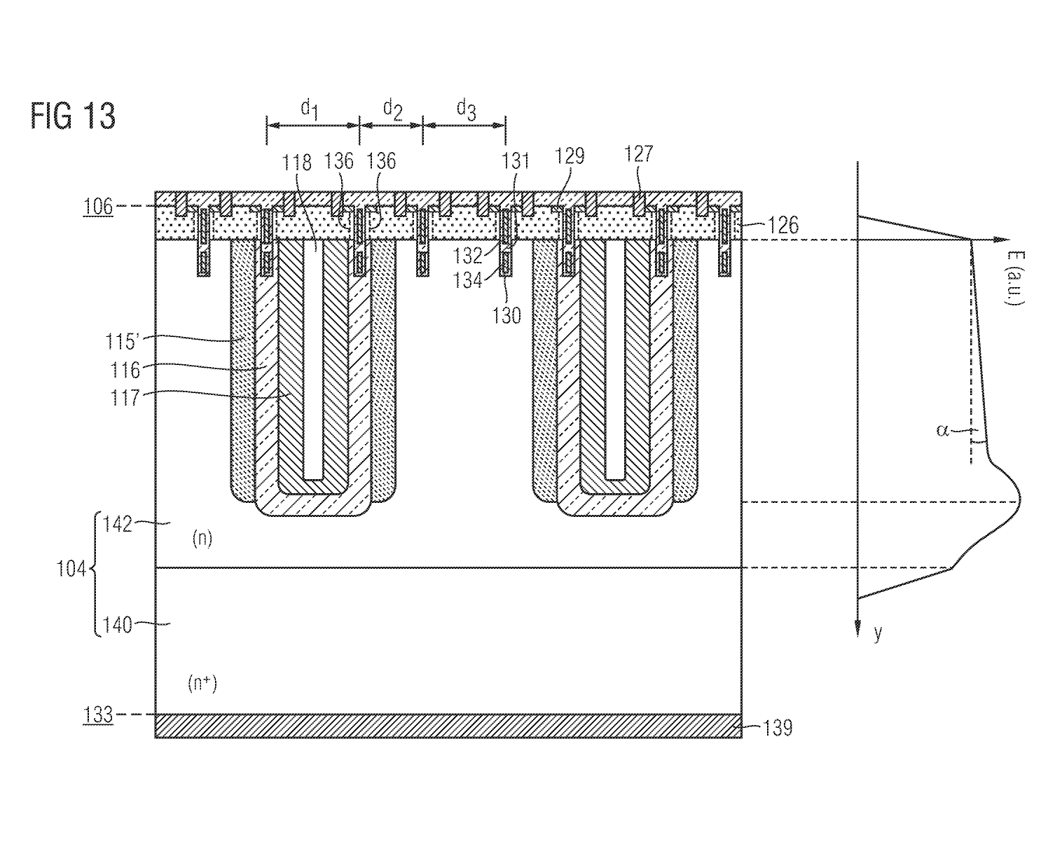

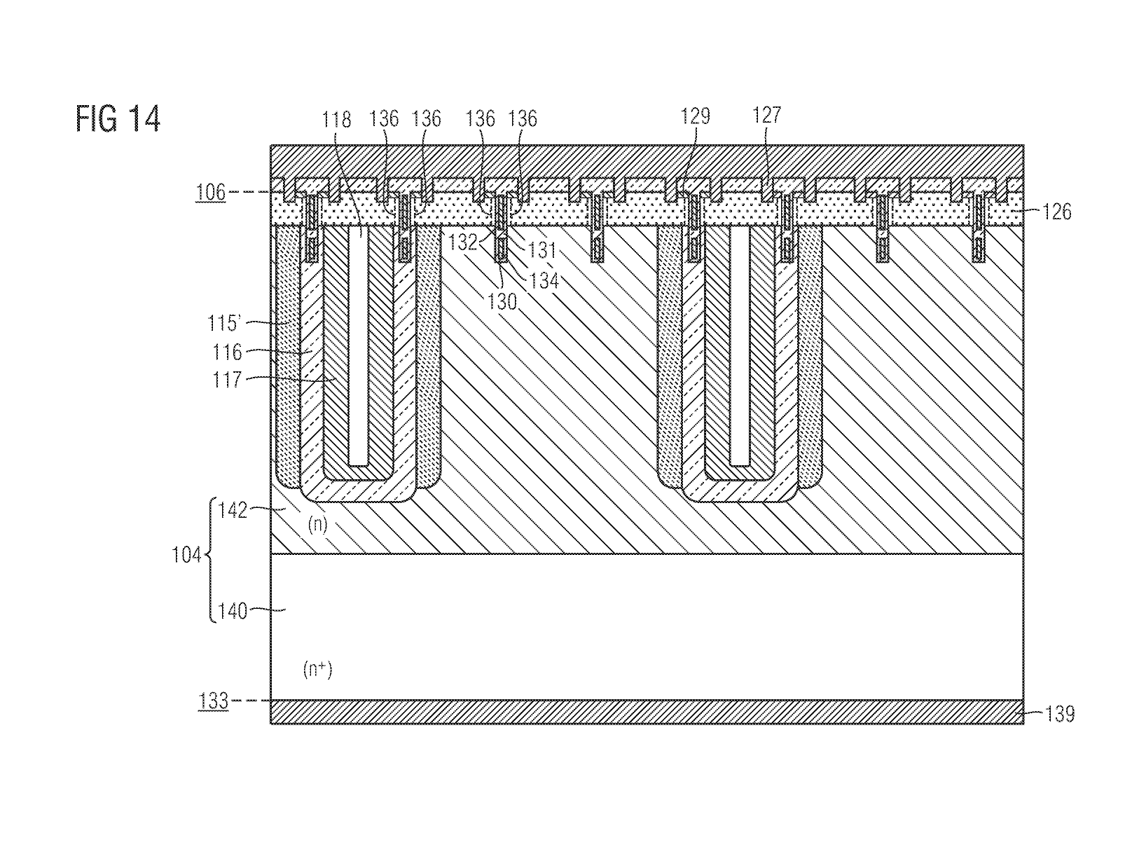

FIG. 13 illustrates one embodiment of a super junction semiconductor device including a super junction structure with the U-shaped third p-doped semiconductor layer 117 and two types of drift regions. A first type of drift region corresponds to a part of the n-doped semiconductor body 104 between neighboring third p-doped semiconductor layers 117. The first type of drift region includes two gate trenches 130 therein. A second type of drift region corresponds to the second n-doped semiconductor layer 116. Gate trenches 130 in opposite sidewall portions of the third p-doped semiconductor layer 117 are at a distance d₁. Neighboring gate trenches 130 ending in the second n-doped semiconductor layer 116 and in the n-doped semiconductor body 104, respectively, are at a distance d2. Neighboring gate trenches 130 ending in the n-doped semiconductor body 104 are at a distance d3. In the embodiment illustrated in FIG. 13, the distances d1, d2, d3 differ from each other. In the embodiment of a super junction semiconductor device illustrated in FIG. 14, the distances d1, d2, d3 are equal leading to equally spaced gate trenches.

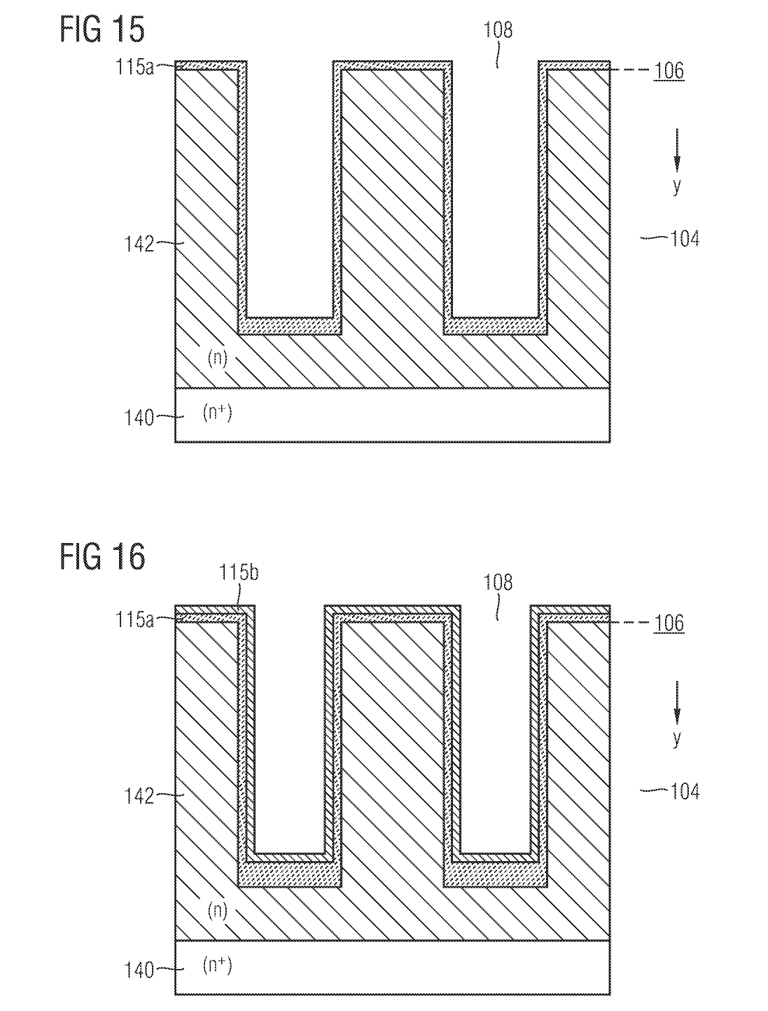

FIG. 15 is a schematic cross-sectional view of a semiconductor body portion for illustrating another embodiment of a method of manufacturing a super junction semiconductor device after forming a first p-doped sub-layer 115a lining sidewalls and a bottom side of the semiconductor body portion illustrated in FIG. 2.

FIG. 16 is a schematic cross-sectional view of the semiconductor body portion of FIG. 15 after forming a second p-doped sub-layer 115b on the first p-doped sub-layer 115a.

An averaged doping concentration of the first p-doped sub-layer 115a is higher than an averaged doping concentration of the second p-doped sub-layer 115b. According to one embodiment, the averaged doping concentration of the first p-doped sub-layer 115a ranges between 5×10¹⁵ cm⁻³ and 5×10¹⁷ cm⁻³ and the averaged doping concentration of the second p-doped sub-layer 115b ranges between 1×10¹⁵ cm⁻³ and 5×10¹⁶ cm⁻³. Electrochemical etching of the second p-doped sub-layer 115b similar to the embodiment described with respect to FIG. 4 leads to the second depletion layer 152 in the first p-doped sub-layer 115a and to the Schottky depletion layer 148 in the second p-doped sub-layer 115b. Formation the first and second p-doped sub-layers 115a, 115b with above-specified different averaged doping concentration allows for a further improvement of charge compensation precision.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method for manufacturing a super junction semiconductor device, the method comprising:
forming a trench in a semiconductor body of a first conductivity type;
forming a first semiconductor layer of a second conductivity type other than the first conductivity type lining sidewalls and a bottom side of the trench;
removing a part of the first semiconductor layer at the side walls and at the bottom side of the trench by electrochemical etching; and
filling the trench.

2. The method of claim 1, wherein removing the part of the first semiconductor layer includes alkaline wet etching of the first semiconductor layer by applying a blocking voltage between an alkaline solution in contact with the first semiconductor layer and with the semiconductor body.

3. The method of claim 1, further comprising, before electrochemical etching,
forming a highly doped region of the first conductivity type in the first semiconductor layer outside the trench by introducing dopants of the first conductivity type in the first semiconductor layer, the highly doped region being configured to electrically couple the first semiconductor layer and an alkaline solution during electrochemical etching.

4. The method of claim 1, wherein forming the first semiconductor layer includes forming a first sub-layer of the second conductivity type, and, thereafter, forming a second sub-layer of the second conductivity type, wherein an averaged doping concentration of the first sub-layer is higher than an averaged doping concentration of the second sub-layer.

5. The method of claim 4, wherein the averaged doping concentration of the first sub-layer ranges between 5×10¹⁵ cm⁻³ and 5×10¹⁷ cm⁻³ and the averaged doping concentration of the second sub-layer ranges between 1×10¹⁵ cm-3 and 5×10¹⁶ cm⁻³.

6. The method of claim 1, further comprising:
forming a source electrode and a gate electrode at a first side of the semiconductor body; and forming a drain electrode at a second side of the semiconductor body opposite to the first side.

7. The method of claim 1, wherein filling the trench includes at least one of forming an intrinsic or a lightly doped semiconductor material in the trench and forming a dielectric material in the trench.

8. The method of claim 1, wherein filling the trench includes filling the trench with a material including a void.

9. The method of claim 1, wherein after forming the trench and before forming the first semiconductor layer, the method further comprises:
forming a third semiconductor layer of the second conductivity type the lining sidewalls and the bottom side of the trench;
removing the third semiconductor layer from the bottom side of the trench; and
forming a fourth semiconductor layer of the first conductivity type lining the sidewalls and the bottom side of the trench.

10. The method of claim 9, wherein forming the third semiconductor layer, removing the third semiconductor layer from the bottom side of the trench and forming the fourth semiconductor layer are performed several times.

11. A super junction semiconductor device, comprising:
a super junction structure including a first U-shaped semiconductor layer of a second conductivity type having opposite sidewalls and a bottom side, wherein each one of the opposite sidewalls of the first U-shaped semiconductor layer adjoins a compensation region of a complementary first conductivity type and the bottom side of the first U-shaped semiconductor layer adjoins a semiconductor body portion of the first conductivity type; and
a filling material filling an inner area of the first U-shaped semiconductor layer,
wherein the filling material is an intrinsic or a lightly doped semiconductor material.

12. (canceled)

13. The super junction semiconductor device of claim 11, wherein the filling material includes a void.

14. The super junction semiconductor device of claim 11, wherein the super junction semiconductor device is a vertical insulated gate field effect transistor (IGBT) including a first load terminal and a control terminal at a first side of a semiconductor body and a second load terminal at a second side of the semiconductor body opposite to the first side.

15. A super junction semiconductor device, comprising:
a super junction structure including a first U-shaped semiconductor layer of a second conductivity type;
a filling material filling an inner area of the first U-shaped semiconductor layer; and
a compensation region of a complementary first conductivity type, wherein
at least one pair of a semiconductor region of the first conductivity type and a semiconductor region of the second conductivity type is arranged between the first U-shaped semiconductor layer and the compensation region.

16. The super junction semiconductor device of claim 15, wherein a width of the compensation region is greater than a width of the semiconductor region of the first conductivity type.

17. The super junction semiconductor device of claim 15, wherein an averaged doping concentration of the compensation region is smaller than an averaged doping concentration of the semiconductor region of the first conductivity type.

18. The super junction semiconductor device of claim 15, wherein the filling material is at least one of an intrinsic or a lightly doped semiconductor material and a dielectric material.

19. The super junction semiconductor device of claim 15, wherein the filling material includes a void.

20. The super junction semiconductor device of claim 15, wherein the super junction semiconductor device is a vertical insulated gate field effect transistor (IGBT) including a first load terminal and a control terminal at a first side of a semiconductor body and a second load terminal at a second side of the semiconductor body opposite to the first side.
